(19) United States
(12) Patent Application Publication
(10) Pub. No.: US 2014/0290742 A1
(43) Pub. Date: Oct. 2, 2014

(54) FRAME STRUCTURE AND SOLAR MODULE HAVING THE SAME

(71) Applicant: AU Optronics Corporation, Hsin-Chu (TW)

(72) Inventors: Yu-Jung CHANG, HSIN-CHU (TW); Huang-Chi TSENG, HSIN-CHU (TW); Hung-Ming TSENG, HSIN-CHU (TW); Yung-Chih CHEN, HSIN-CHU (TW)

(73) Assignee: AU Optronics Corporation, Hsin-Chu (TW)

(21) Appl. No.: 14/054,945

(22) Filed: Oct. 16, 2013

(30) Foreign Application Priority Data
Mar. 27, 2013 (CN) 201310101938.8

(51) Int. Cl. H01L 31/042

(52) U.S. Cl. CPC H01L 31/0424
USPC 136/259; 211/134; 211/26

(57) ABSTRACT

A frame structure includes a first horizontal board, a second horizontal board, a first vertical board, a third horizontal board, a second vertical board, and at least one support element. The first vertical board is connected to the first and second horizontal boards. The second vertical board is connected to the second and third horizontal boards. At least a portion of the second horizontal board and at least a portion of the third horizontal board protrude from the second vertical board, such that an open accommodating space is defined between the second horizontal board, the second vertical board, and the third horizontal board. The support element is detachably positioned in the accommodating space. A top surface of the support element is abutted against the second horizontal board, and a bottom surface of the support element is abutted against the third horizontal board.

### RELATED APPLICATIONS

This application claims priority to Chinese Application Serial Number 201310101938.8, filed Mar. 27, 2013, which is herein incorporated by reference.

### BACKGROUND

1. Technical Field

The present disclosure relates to a frame structure and a solar module having the same.

2. Description of Related Art

In order to improve the strength of solar modules, aluminum frames are often used at side edges of solar panels for protection. A mechanical load test is an important test for solar modules. For example, a solar module having 60 solar cells needs to be able to withstand a 400 kg force to pass a 2400 Pa mechanical load test, and a 900 kg force to pass a 5400 Pa mechanical load test.

Designers can improve the strength of the solar module by improving the strength of the glass and the aluminum frame located on the solar panel. However, although increasing the thickness of the glass can improve the strength of the solar module, glass makes up 65% of the total weight of the solar module, and so the weight of the solar module would be greatly increased if the thickness of the glass were increased, resulting in inconvenience when users move and assemble the solar module. Therefore, the thickness of the aluminum frame is usually increased instead when it is desired to improve the strength of the solar module. Nevertheless, a thicker aluminum frame results in a heavier weight and also a higher material cost. Furthermore, since the aluminum frame is manufactured by an aluminum extrusion process, support pillars perpendicular to the length direction of the aluminum frame cannot be formed, and instead, only support pillars having the same length as the aluminum frame can be formed. The formation of such support pillars runs counter to efforts to reduce cost.

Furthermore, the strength of the aluminum frame after being completely manufactured cannot be changed. For example, a solar module that needs to pass the 2400 Pa mechanical load test can only use an aluminum frame that is designed to withstand such a load condition. If such an aluminum frame is assembled to another solar module that needs to pass the 5400 Pa mechanical load test, the solar module will not pass the mechanical load test. That is to say, one aluminum frame cannot be used on different solar modules that need to pass different mechanical load tests, thus causing inconvenience.

### SUMMARY

An aspect of the present invention is to provide a frame structure.

According to an embodiment of the present invention, a frame structure includes a first horizontal board, a second horizontal board, a first vertical board, a third horizontal board, a second vertical board, and at least a support element. A first gap is formed between the first and second horizontal boards. The first vertical board is connected to the first and second horizontal boards. A second gap is formed between the second and third horizontal boards. The second vertical board is connected to the second and third horizontal boards. At least a portion of the second horizontal board and at least a portion of the third horizontal board protrude from the second vertical board, such that an open accommodating space is defined between the second horizontal board, the second vertical board, and the third horizontal board. The support element is detachably positioned in the accommodating space. A top surface of the support element is abutted against the second horizontal board, and a bottom surface of the support element is abutted against the third horizontal board.

In one or more embodiments of the present invention, a side surface of the support element is abutted against the second vertical board.

In one or more embodiments of the present invention, the first vertical board is connected to the third horizontal board, and a third gap is formed between the third horizontal board and the second vertical board.

In one or more embodiments of the present invention, a surface of the second horizontal board facing the accommodating space has a recess. The support element has a protruding block. The protruding block is flexibly disposed on the top surface of the support element for being coupled to the recess.

In one or more embodiments of the present invention, the support element includes a partition board and a spring connected between the partition board and the protruding block.

In one or more embodiments of the present invention, the support element includes a concave portion, and the concave portion and the protruding block have screw threads for coupling with each other.

In one or more embodiments of the present invention, a surface of the third horizontal board facing the accommodating space has a recess. The support element has a protruding block. The protruding block is flexibly disposed on the bottom surface of the support element for being coupled to the recess.

In one or more embodiments of the present invention, the support element includes a partition board and a spring connected between the partition board and the protruding block.

In one or more embodiments of the present invention, the support element includes a concave portion. The concave portion and the protruding block have screw threads for coupling with each other.

In one or more embodiments of the present invention, the second horizontal board has a first free end. A distance between a connection position of the second horizontal board and the second vertical board and the first free end is substantially equal to a length of the top surface of the support element.

In one or more embodiments of the present invention, the third horizontal board has a second free end. A distance between a connection position of the third horizontal board and the second vertical board and the second free end is substantially equal to a length of the bottom surface of the support element.

In one or more embodiments of the present invention, a cross-sectional area of the support element is substantially equal to (L1+L2)×(d2)/2. L1 is the distance between the connection position of the second horizontal board and the second vertical board and the first free end, L2 is the distance between the connection position of the third horizontal board and the second vertical board and the second free end, and d2 is the second gap.

In one or more embodiments of the present invention, the second horizontal board has a first free end. A distance between a connection position of the second horizontal board and the second vertical board and the first free end is greater than a length of the top surface of the support element.

In one or more embodiments of the present invention, the third horizontal board has a second free end. A distance between a connection position of the third horizontal board and the second vertical board and the second free end is greater than a length of the bottom surface of the support element.

In one or more embodiments of the present invention, a distance between the top and bottom surfaces of the support element is greater than a distance between the second and third horizontal boards.

In one or more embodiments of the present invention, a distance between the top and bottom surfaces of the support element is substantially equal to a distance between the second and third horizontal boards.

In one or more embodiments of the present invention, a frame assembly is formed by the first, second, and third horizontal boards, and the first and second vertical boards, and the frame assembly has the same cross-sectional shape along a length direction thereof.

In one or more embodiments of the present invention, the hardness of the support element is greater than the hardness of each of the first, second, and third horizontal boards, and the first and second vertical boards.

In one or more embodiments of the present invention, the first, second, and third horizontal boards, and the first and second vertical boards are formed as a single piece.

In one or more embodiments of the present invention, the first, second, and third horizontal boards, and the first and second vertical boards are made of a material that includes aluminum.

In one or more embodiments of the present invention, the support element is made of a material that includes plastic, gold, silver, copper, iron, alloy, or combinations thereof.

In one or more embodiments of the present invention, the shape of the support element is trapezoidal, cubical, or cylindrical.

In one or more embodiments of the present invention, a groove is defined between the first horizontal board, the first vertical board, and the second horizontal board for engaging with a side edge of a solar cell.

Another aspect of the present invention is to provide a solar module.

According to an embodiment of the present invention, a solar module includes a solar cell and a frame structure. The solar cell has a side edge. The frame structure includes a first horizontal board, a second horizontal board, a first vertical board, a third horizontal board, a second vertical board, and at least a support element. A first gap is formed between the first and second horizontal boards. The first vertical board is connected to the first and second horizontal boards. A groove is defined between the first horizontal board, the first vertical board, and the second horizontal board for engaging with the side edge of the solar cell. A second gap is formed between the second and third horizontal boards. The second vertical board is connected to the second and third horizontal boards. At least a portion of the second horizontal board and at least a portion of the third horizontal board protrude from the second vertical board, such that an open accommodating space is defined between the second horizontal board, the second vertical board, and the third horizontal board. The support element is detachably positioned in the accommodating space. A top surface of the support element is abutted against the second horizontal board, and a bottom surface of the support element is abutted against the third horizontal board.

In the aforementioned embodiments of the present invention, since the top surface of the support element is abutted against the second horizontal board, and the bottom surface of the support element is abutted against the third horizontal board, when the frame structure is engaged with the solar cell, the strength of the whole solar module can be enhanced. Moreover, the support element is detachably positioned in the accommodating space between the second horizontal board, the second vertical board, and the third horizontal board. Therefore, when the frame structure is used, the number of the support elements can be decided depending on the load condition of the solar module, and the frame assembly formed by the first, second, and third horizontal boards, and the first and second vertical boards does not need to be changed.

That is to say, when the strength of the solar module needs to be enhanced, the thicknesses of the first, second, and third horizontal boards, and the first and second vertical boards do not need to be increased, and the strength of the solar module can be enhanced simply by using more support elements. As a result, the material cost of the frame structure can be reduced.

### BRIEF DESCRIPTION OF THE DRAWINGS

FIG. 1A is an exploded view of a solar module according to an embodiment of the present invention;

FIG. 1B is an exploded view of a solar module according to an embodiment of the present invention;

FIG. 2 is a side view of a frame structure shown in FIG. 1B, in which the side view is seen from a direction D;

FIG. 3 is a perspective view of a support element shown in FIG. 2;

FIG. 4 is a partial perspective view of a frame structure according to an embodiment of the present invention when support elements are removed;

FIG. 5 is a perspective view of a support element according to an embodiment of the present invention;

FIG. 6 is a perspective view of a support element according to an embodiment of the present invention;

FIG. 7 is a partial perspective view of the frame structure shown in FIG. 4 when the support elements shown in FIG. 5 and FIG. 6 are positioned in an accommodating space;

FIG. 8 is a perspective view of a frame structure according to an embodiment of the present invention;

FIG. 9 is a perspective view of a frame structure according to an embodiment of the present invention;

FIG. 10 is a perspective view of a frame structure according to an embodiment of the present invention;

FIG. 11 is a side view of a frame structure according to an embodiment of the present invention;

FIG. 12 is a side view of a frame structure according to an embodiment of the present invention;

FIG. 13 is a side view of a frame structure according to an embodiment of the present invention;

FIG. 14 is a side view of a frame structure according to an embodiment of the present invention; and

FIG. 15 is a side view of a frame structure according to an embodiment of the present invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

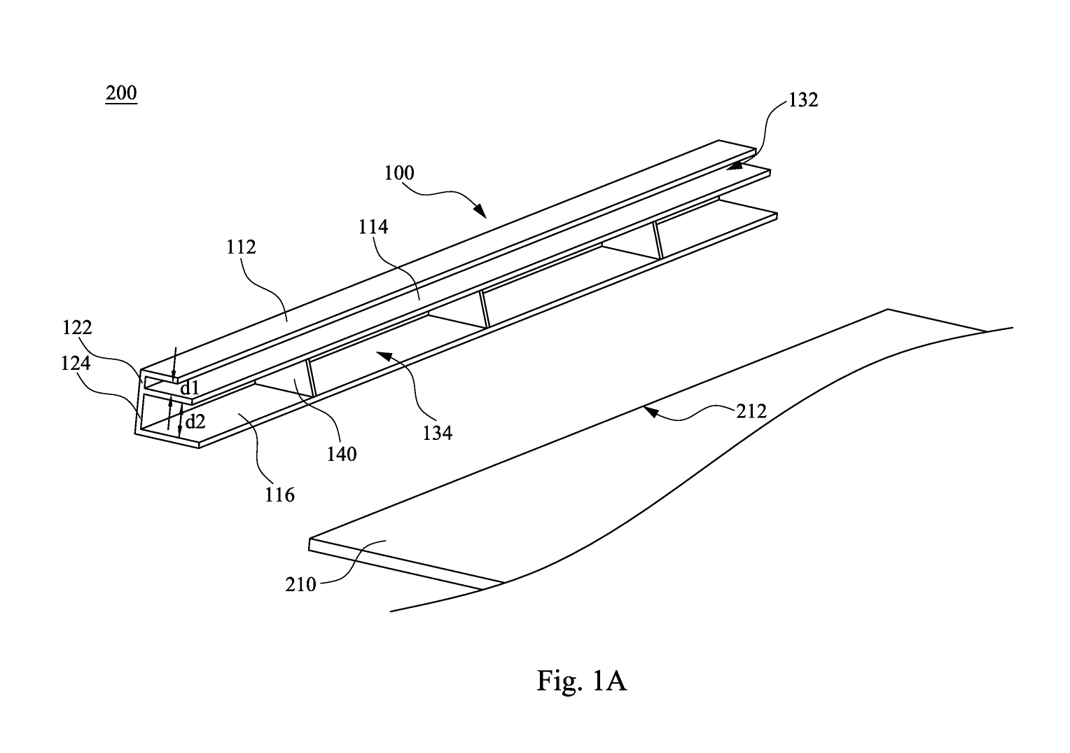

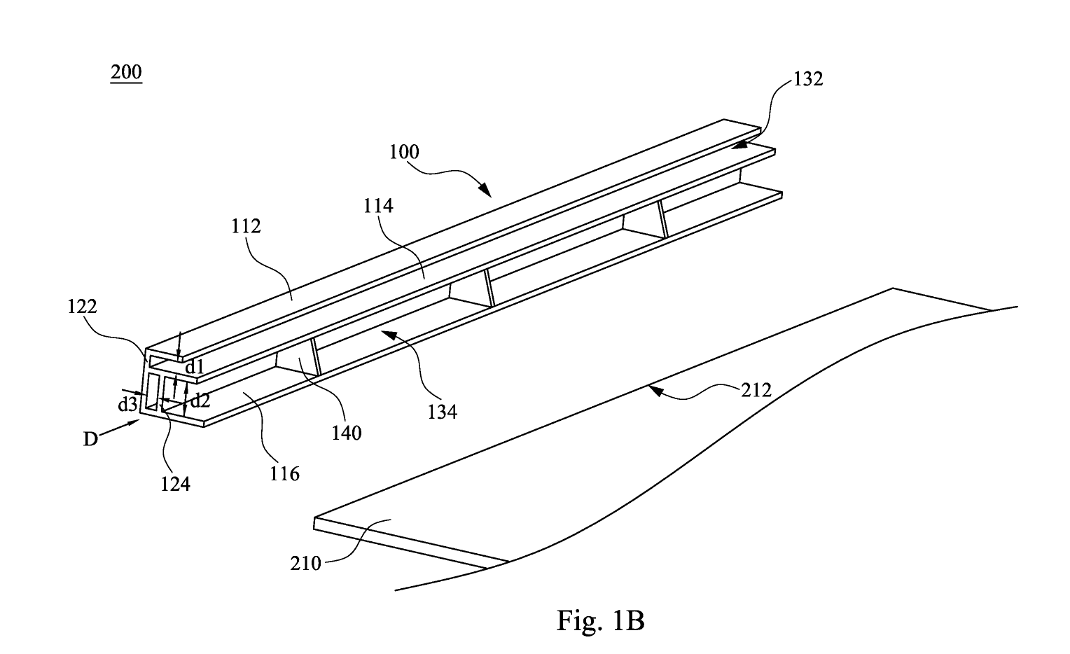

FIG. 1A is an exploded view of a solar module 200 according to an embodiment of the present invention. As shown in FIG. 1A, the solar module 200 includes a solar cell 210 and a frame structure 100. The frame structure 100 includes a first horizontal board 112, a second horizontal board 114, a first vertical board 122, a third horizontal board 116, a second vertical board 124, and a support element 140. A first gap d1 is formed between the first and second horizontal boards 112, 114. The first vertical board 122 is connected to the first and second horizontal boards 112, 114, such that a groove 132 is defined between the first horizontal board 112, the first vertical board 122, and the second horizontal board 114. The groove 132 can be engaged with a side edge 212 of the solar cell 210. As a result, the solar cell 210 can be protected and supported by the frame structure 100.

A second gap d2 is formed between the second and third horizontal boards 114, 116, and the second vertical board 124 is connected to the second and third horizontal boards 114, 116. In this embodiment, the first and second vertical boards 122, 124 are coplanar, but in another embodiment, the first and second vertical boards 122, 124 may be unaligned. Moreover, at least a portion of the second horizontal board 114 and at least a portion of the third horizontal board 116 protrude from the second vertical board 124, such that an open accommodating space 134 can be defined between the second horizontal board 114, the second vertical board 124, and the third horizontal board 116.

The first, second, and third horizontal boards 112, 114, 116, and the first and second vertical boards 122, 124 may made of a material that includes aluminum, and these boards can be manufactured by an aluminum extrusion process. As a result, a frame assembly formed by the first, second, and third horizontal boards 112, 114, 116, and the first and second vertical boards 122, 124 has the same cross-sectional shape along the length direction thereof. Furthermore, the first, second, and third horizontal boards 112, 114, 116, and the first and second vertical boards 122, 124 are formed as a single piece.

The support element 140 is detachably positioned in the accommodating space 134. For example, the support element 140 can be positioned between the second and third horizontal boards 114, 116 by a friction engagement with the same. The hardness of the support element 140 may be greater than the hardness of the first, second, and third horizontal boards 112, 114, 116, and the first and second vertical boards 122, 124. Moreover, the support element 140 may made of a material that includes plastic, gold, silver, copper, iron, alloy, or combinations thereof. For instance, when the frame assembly formed by the first, second, and third horizontal boards 112, 114, 116, and the first and second vertical boards 122, 124 is made of aluminum 6063-T5, a material having a hardness greater than the hardness of aluminum 6063-T5 can be chosen to manufacture the support element 140 to thereby improve the strength of the frame structure 100.

In addition, the shape of the support element 140 may be trapezoidal, cubical, or cylindrical as deemed necessary by designers.

FIG. 1B is an exploded view of a solar module 200 according to an embodiment of the present invention. The frame structure 100 includes the first horizontal board 112, the second horizontal board 114, the first vertical board 122, the third horizontal board 116, the second vertical board 124, and the support element 140. The difference between this embodiment and the embodiment shown in FIG. 1A is that the first vertical board 122 is connected to the third horizontal board 116, and a third gap d3 is formed between the third horizontal board 116 and the second vertical board 124.

In the following description, the frame structure 100 shown in FIG. 1B will be used as an example to describe the structure and positioning method of the support element 140.

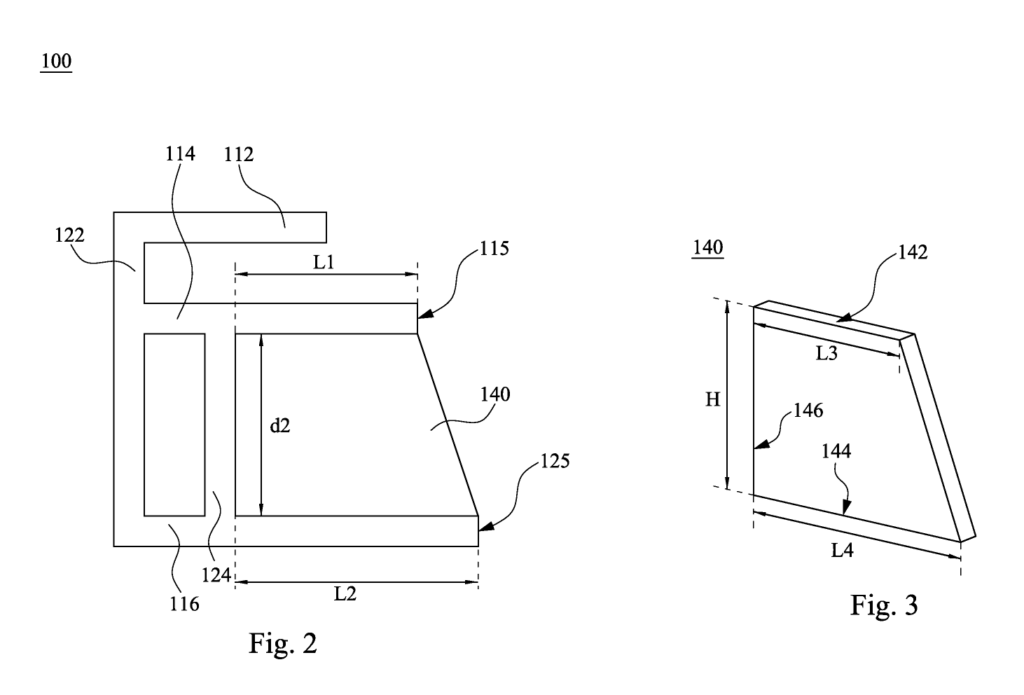

FIG. 2 is a side view of the frame structure 100 shown in FIG. 1B, in which the side view is seen from a direction D. FIG. 3 is a perspective view of the support element 140 shown in FIG. 2. As shown in FIG. 2 and FIG. 3, the second horizontal board 114 has a first free end 115. A distance L1 between the connection position of the second horizontal board 114 and the second vertical board 124 and the first free end 115 is substantially equal to a length L3 of a top surface 142 of the support element 140. “Substantially” is used herein to refer to the fact that there may be differences as a result of manufacturing errors. The third horizontal board 116 has a second free end 125. A distance L2 between the connection position of the third horizontal board 116 and the second vertical board 124 and the second free end 125 is substantially equal to a length L4 of a bottom surface 144 of the support element 140. A distance H between the top surface 142 and the bottom surface 144 of the support element 140 is substantially equal to a distance between the second and third horizontal boards 114, 116 (i.e., the second gap d2). That is to say, in this embodiment, the cross-sectional area of the support element 140 is substantially equal to (L1+L2)×(d2)/2.

Since the top surface 142 of the support element 140 is completely abutted against the second horizontal board 114 protruding from the second vertical board 124, a side surface 146 of the support element 140 is completely abutted against the second vertical board 124, and the bottom surface 144 of the support element 140 is completely abutted against the third horizontal board 116 protruding from the second vertical board 124, the support element 140 of this embodiment can provide a good support strength to the frame structure 100, and moreover, the material for manufacturing the support element 140 is not wasted. For example, if the length L3 of the top surface 142 were greater than the distance L1, the material of such a support element 140 would be wasted since the strength of the frame structure 100 would not be further enhanced with the use of such a support element 140.

In addition, since the second and third horizontal boards 114, 116 may be made of aluminum, the second and third horizontal boards 114, 116 have elasticity. As a result, the distance H between the top surface 142 and the bottom surface 144 of the support element 140 may be greater than the distance between the second and third horizontal boards 114, 116 (i.e., the second gap d2), such that a better positioning capability is provided with respect to the support element 140 between the second and third horizontal boards 114, 116.

Referring to FIG. 1B and FIG. 2, since the top surface 142 of the support element 140 is abutted against the second horizontal board 114, and the bottom surface 144 of the support element 140 is abutted against the third horizontal board 116, when the frame structure 100 is engaged with the solar cell 210, the strength of the whole solar module 200 can be enhanced. The support element 140 is detachably positioned in the accommodating space 134 between the second horizontal board 114, the second vertical board 124, and the third horizontal board 116. Therefore, when the frame structure 100 is used, the number of the support elements 140 can be decided depending on the load condition of the solar module 200, and the frame assembly formed by the first, second, and third horizontal boards 112, 114, 116, and the first and second vertical boards 122, 124 does not need to be changed.

The frame structure 100 can be widely used. When the strength of the solar module 200 needs to be increased (or reduced), the thicknesses of the first, second, and third horizontal boards 112, 114, 116, and the first and second vertical boards 122, 124 do not need to be increased (or decreased), and it is necessary only to assemble more (or less) support elements 140, such that the material cost of the frame structure 140 can be reduced. For example, a solar module 200 that needs to pass 2400 Pa and 5400 Pa mechanical load tests can use the same frame assembly, and calculations can be performed to determine the number of the frame structures 140 needed to assemble to the frame assembly depending on these mechanical load tests. Therefore, the frame assembly of the solar module 200 does not need to be changed.

Moreover, since the frame structure 140 is detachably positioned between the second and third horizontal boards 114, 116, the weight of the solar module 200 is not significantly increased, resulting in convenience when users move and assemble the solar module 200. The frame structure 140 functions as a support pillar perpendicular to the length direction of the frame structure 100, and is not a support pillar formed by aluminum extrusion process and having the same length as the first, second, and third horizontal boards 112, 114, 116. Therefore, the cost of the frame structure 140 can be reduced.

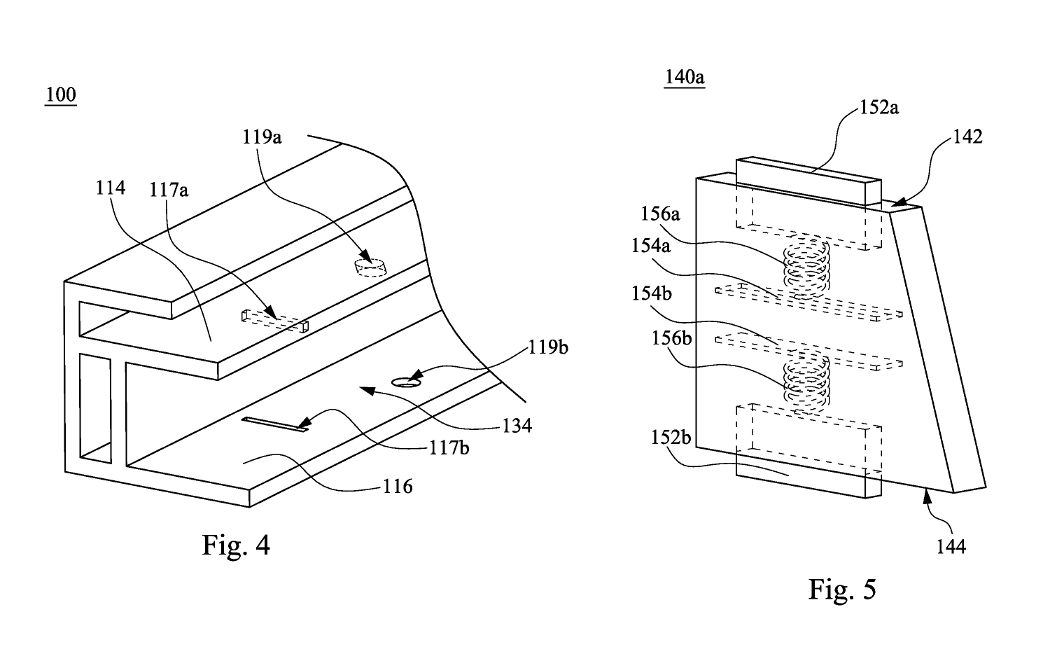

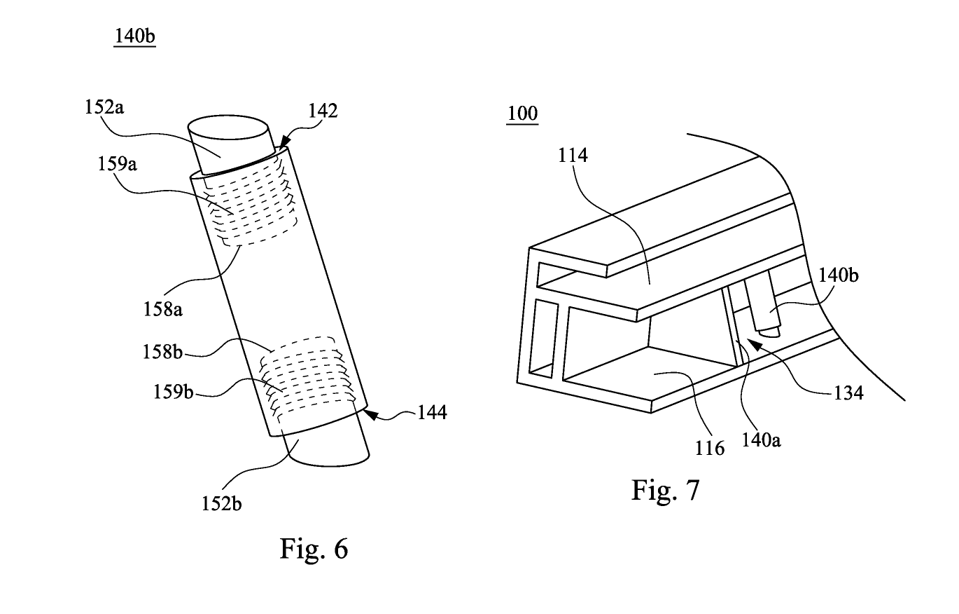

FIG. 4 is a partial perspective view of a frame structure 100 according to an embodiment of the present invention when support elements 140a, 140b (see FIG. 5 and FIG. 6) are removed. FIG. 5 is a perspective view of a support element 140a according to an embodiment of the present invention. As shown in FIG. 4 and FIG. 5, a surface of the second horizontal board 114 facing the accommodating space 134 has a recess 117a. A surface of the third horizontal board 116 facing the accommodating space 134 has a recess 117b. The support element 140a may further include protruding blocks 152a, 152b, partition boards 154a, 154b, and springs 156a, 156b.

The spring 156a is connected between the partition board 154a and the protruding block 152a, such that the protruding block 152a is flexibly disposed on the top surface 142 of the support element 140a. The spring 156b is connected between the partition board 154b and the protruding block 152b, such that the protruding block 152b is flexibly disposed on the bottom surface 144 of the support element 140a.

FIG. 6 is a perspective view of a support element 140b according to an embodiment of the present invention. As shown in FIG. 4 and FIG. 6, the surface of the second horizontal board 114 facing the accommodating space 134 may further have a recess 119a. A surface of the third horizontal board 116 facing the accommodating space 134 may further have a recess 119b. The support element 140b may include protruding blocks 152a, 152b and concave portions 158a, 158b. The concave portion 158a and the protruding block 152a have screw threads for coupling with each other, and the concave portion 158b and the protruding block 152b also have screw threads for coupling with each other. The protruding blocks 152a, 152b can be extended from or contracted into the concave portions 158a, 158b by rotating the protruding blocks 152a, 152b in the concave portions 158a, 158b, such that the protruding blocks 152a, 152b can be respectively disposed on the top and bottom surfaces 142, 144 of the support element 140b in an adjustable manner.

FIG. 7 is a partial perspective view of the frame structure 100 shown in FIG. 4 when the support elements 140a, 140b shown in FIG. 5 and FIG. 6 are positioned in the accommodating space 134. When the support elements 140a, 140b are assembled between the second and third horizontal boards 114, 116, the protruding blocks 152a, 152b of the support element 140a shown in FIG. 5 can be respectively coupled to the recesses 117a, 117b (see FIG. 4), and the protruding blocks 152a, 152b of the support element 140b shown in FIG. 6 can be respectively coupled to the recesses 119a, 119b (see FIG. 4). As a result, the support elements 140a, 140b can be positioned in the accommodating space 134.

It is to be noted that the connection relationships of the elements described above will not be repeated in the following description.

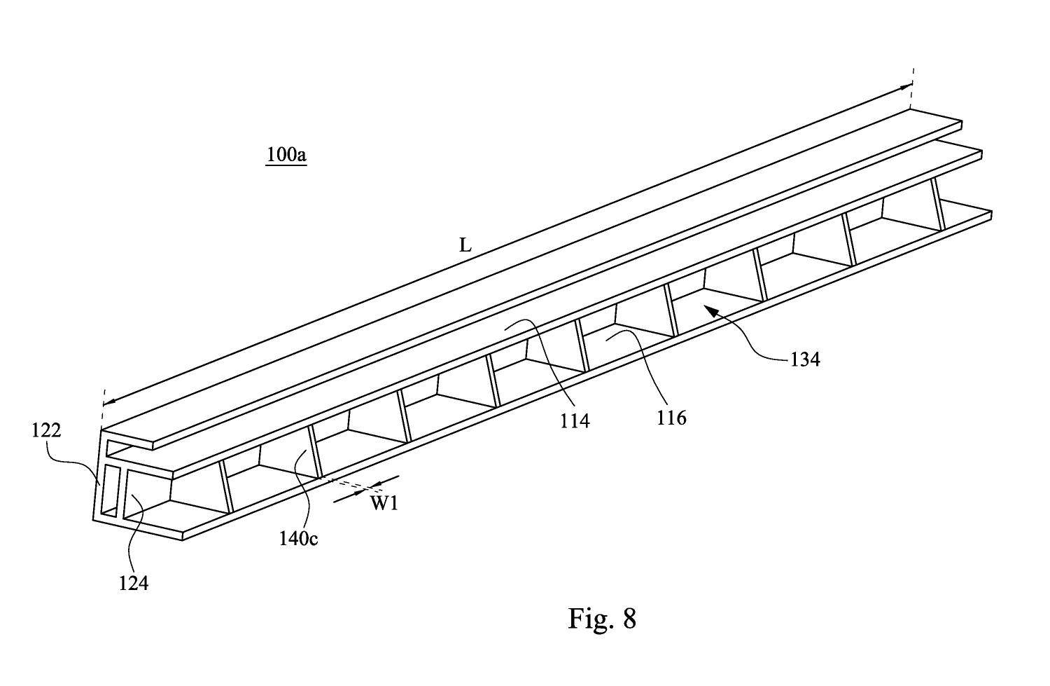

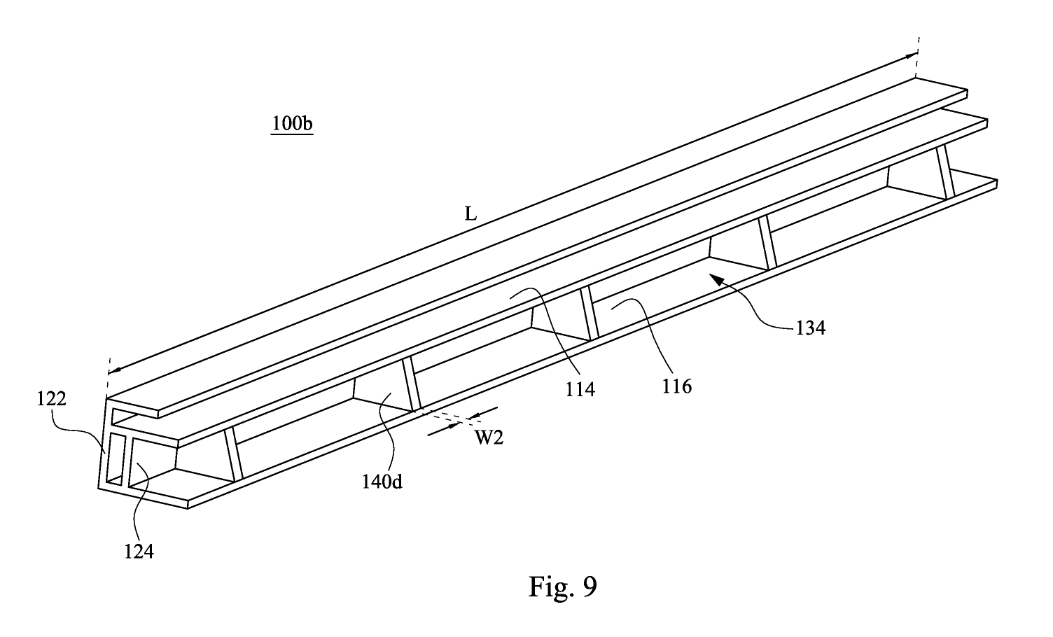

FIG. 8 is a perspective view of a frame structure 100a according to an embodiment of the present invention. FIG. 9 is a perspective view of a frame structure 100b according to an embodiment of the present invention. As shown in FIG. 8 and FIG. 9, the frame structures 100a, 100b have the same length L. The cross-sectional shape of a support element 140c of the frame structure 100a and the cross-sectional shape of a support element 140d of the frame structure 100b are the same (e.g., they are trapezoidal as shown in the drawings), but the thickness W1 of the support element 140c is smaller than the thickness W2 of the support element 140d. Therefore, when the required strengths of the frame structures 100a, 100b are the same, the number of the support elements 140d located in the accommodating space 134 can be smaller than the number of the support elements 140c located in the accommodating space 134.

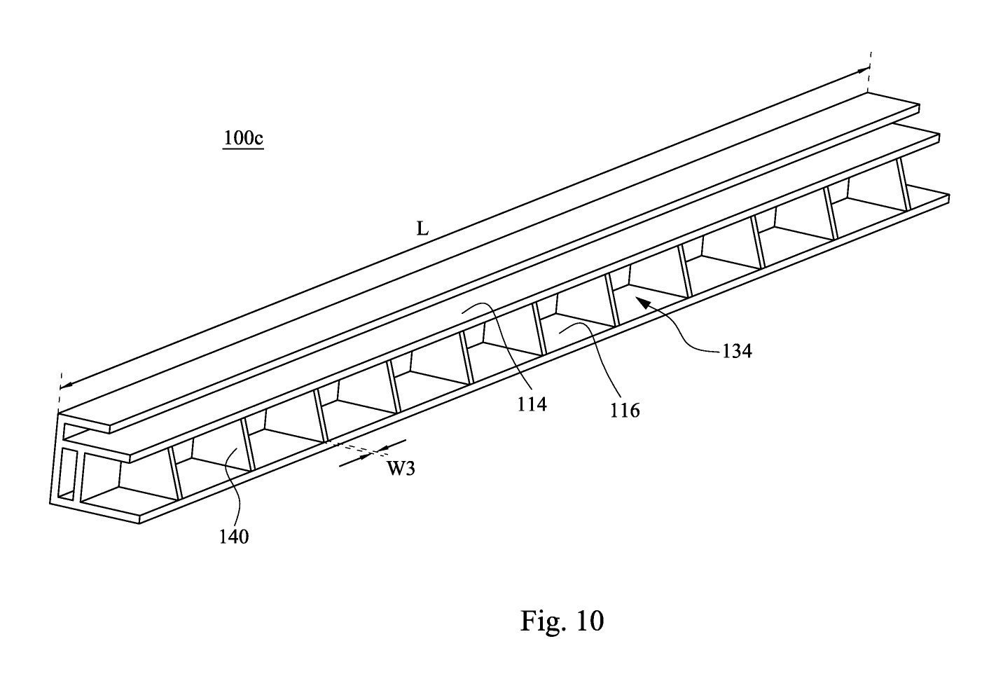

FIG. 10 is a perspective view of a frame structure 100c according to an embodiment of the present invention. When the amount of the material of the support elements 140 is constant, the number of the support elements 140 and the thickness of the support elements 140 can be decided for the best configuration through calculations, such that the frame structure 100c has a great strength. For example, when the length L of the frame structure 100c is substantially 1668 mm and the thickness W3 of each of the support elements 140 is substantially 5 mm, it has been determined that the best configuration of the frame structure 100c is that in which each two adjacent support elements 140 has a 150 mm interval therebetween and the number of the support elements 140 used in the frame structure 100c is eleven. In this case, regardless of whether the thickness of the support elements 140 is increased and the number of the support elements 140 is decreased, or the thickness of the support elements 140 is decreased and the number of the support elements 140 is increased, the strength of the frame structure 100c will be reduced. Moreover, if the aforesaid best configuration is not used and the strength of the frame structure 100c is the same, the material cost of all of the support elements 140 will be increased.

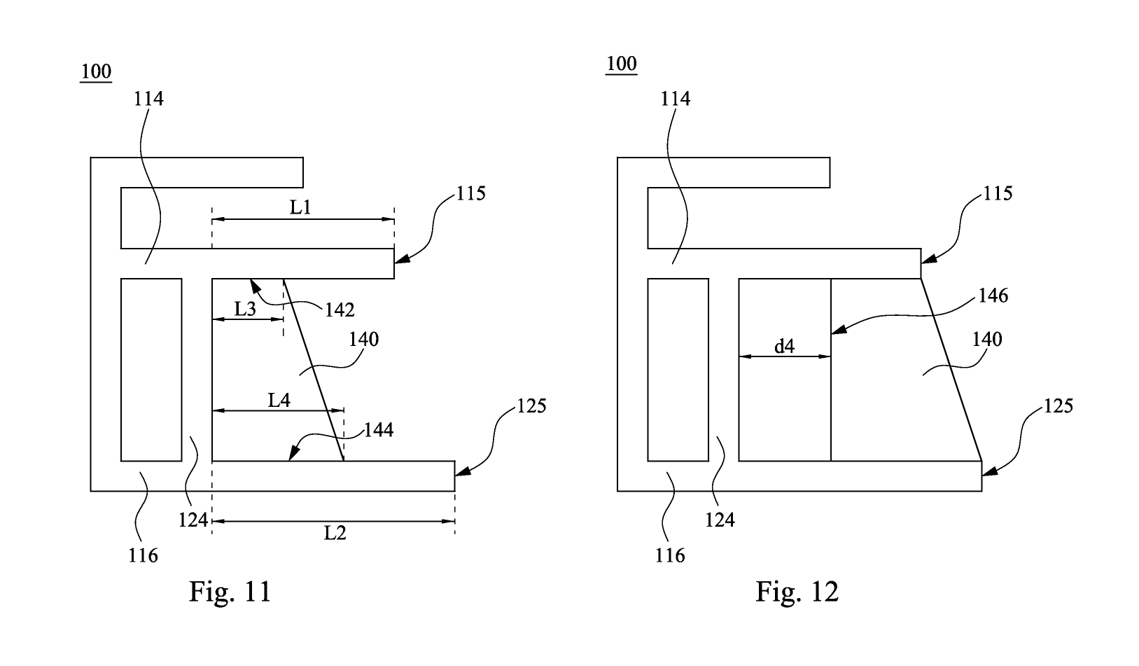

FIG. 11 is a side view of a frame structure 100 according to an embodiment of the present invention. The difference between this embodiment and the embodiment shown in FIG. 2 is that the distance L1 between the connection position of the second horizontal board 114 and the second vertical board 124 and the first free end 115 is greater than the length L3 of the top surface 142 of the support element 140. Moreover, the distance L2 between the connection position of the third horizontal board 116 and the second vertical board 124 and the second free end 125 is greater than the length L4 of the bottom surface 144 of the support element 140.

FIG. 12 is a side view of a frame structure 100 according to an embodiment of the present invention. The difference between this embodiment and the embodiment shown in FIG. 11 is that a space with a distance d4 is formed between the side surface 146 of the support element 140 and the second vertical board 124. The size of the distance d4 can be set in accordance with the position of the support element 140.

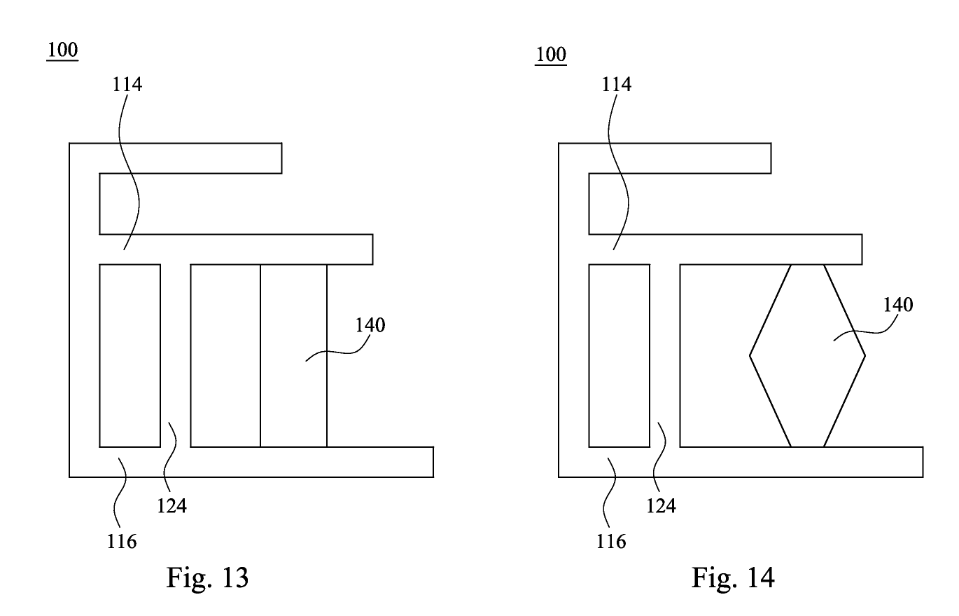

FIG. 13 is a side view of a frame structure 100 according to an embodiment of the present invention. The difference between this embodiment and the embodiment shown in FIG. 12 is that the shape of the support element 140 is cuboidal or cylindrical.

FIG. 14 is a side view of a frame structure 100 according to an embodiment of the present invention. The difference between this embodiment and the embodiment shown in FIG. 13 is that the shape of the support element 140 is hexahedronal.

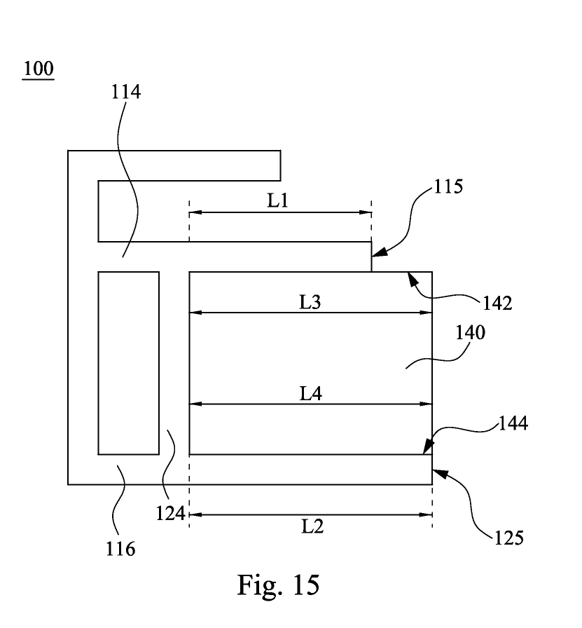

FIG. 15 is a side view of a frame structure 100 according to an embodiment of the present invention. The difference between this embodiment and the embodiment shown in FIG. 2 is that the shape of the support element 140 is cubical, and the length L3 of the top surface 142 of the support element 140 is greater than the distance L1.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A frame structure comprising:
a first horizontal board;
a second horizontal board, wherein a first gap is formed between the first and second horizontal boards;
a first vertical board connected to the first and second horizontal boards;
a third horizontal board, wherein a second gap is formed between the second and third horizontal boards;
a second vertical board connected to the second and third horizontal boards, wherein at least a portion of the second horizontal board and at least a portion of the third horizontal board protrude from the second vertical board, such that an open accommodating space is defined between the second horizontal board, the second vertical board, and the third horizontal board; and
at least a support element detachably positioned in the accommodating space, wherein a top surface of the support element is abutted against the second horizontal board, and a bottom surface of the support element is abutted against the third horizontal board.

2. The frame structure of claim 1, wherein a side surface of the support element is abutted against the second vertical board.

3. The frame structure of claim 1, wherein the first vertical board is connected to the third horizontal board, and a third gap is formed between the third horizontal board and the second vertical board.

4. The frame structure of claim 1, wherein a surface of the second horizontal board facing the accommodating space has a recess, the support element has a protruding block, and the protruding block is flexibly disposed on the top surface of the support element for being coupled to the recess.

5. The frame structure of claim 4, wherein the support element comprises a partition board and a spring connected between the partition board and the protruding block.

6. The frame structure of claim 4, wherein the support element comprises a concave portion, and the concave portion and the protruding block have screw threads for coupling with each other.

7. The frame structure of claim 1, wherein a surface of the third horizontal board facing the accommodating space has a recess, the support element has a protruding block, and the protruding block is flexibly disposed on the bottom surface of the support element for being coupled to the recess.

8. The frame structure of claim 7, wherein the support element comprises a partition board and a spring connected between the partition board and the protruding block.

9. The frame structure of claim 7, wherein the support element comprises a concave portion, and the concave portion and the protruding block have screw threads for coupling with each other.

10. The frame structure of claim 1, wherein the second horizontal board has a first free end, and a distance between a connection position of the second horizontal board and the second vertical board and the first free end is substantially equal to a length of the top surface of the support element.

11. The frame structure of claim 10, wherein the third horizontal board has a second free end, and a distance between a connection position of the third horizontal board and the second vertical board and the second free end is substantially equal to a length of the bottom surface of the support element.

12. The frame structure of claim 11, wherein a cross-sectional area of the support element is substantially equal to (L1+L2)×(d2)/2, where L1 is the distance between the connection position of the second horizontal board and the second vertical board and the first free end, L2 is the distance between the connection position of the third horizontal board and the second vertical board and the second free end, and d2 is the second gap.

13. The frame structure of claim 1, wherein the second horizontal board has a first free end, and a distance between a connection position of the second horizontal board and the second vertical board and the first free end is greater than a length of the top surface of the support element.

14. The frame structure of claim 1, wherein the third horizontal board has a second free end, and a distance between a connection position of the third horizontal board and the second vertical board and the second free end is greater than a length of the bottom surface of the support element.

15. The frame structure of claim 1, wherein a distance between the top and bottom surfaces of the support element is greater than a distance between the second and third horizontal boards.

16. The frame structure of claim 1, wherein a distance between the top and bottom surfaces of the support element is substantially equal to a distance between the second and third horizontal boards.

17. The frame structure of claim 1, wherein a frame assembly is formed by the first, second, and third horizontal boards, and the first and second vertical boards, and the frame assembly has the same cross-sectional shape along a length direction thereof.

18. The frame structure of claim 1, wherein the hardness of the support element is greater than the hardness of each of the first, second, and third horizontal boards, and the first and second vertical boards.

19. The frame structure of claim 1, wherein the first, second, and third horizontal boards, and the first and second vertical boards are formed as a single piece.

20. The frame structure of claim 1, wherein the first, second, and third horizontal boards, and the first and second vertical boards are made of a material that comprises aluminum.

21. The frame structure of claim 1, wherein the support element is made of a material that comprises plastic, gold, silver, copper, iron, alloy, or combinations thereof.

22. The frame structure of claim 1, wherein the shape of the support element is trapezoidal, cubical, or cylindrical.

23. The frame structure of claim 1, wherein a groove is defined between the first horizontal board, the first vertical board, and the second horizontal board for engaging with a side edge of a solar cell.

24. A solar module comprising:
a solar cell having a side edge; and
a frame structure comprising:
a first horizontal board;
a second horizontal board, wherein a first gap is formed between the first and second horizontal boards;
a first vertical board connected to the first and second horizontal boards, wherein a groove is defined between the first horizontal board, the first vertical board, and the second horizontal board for engaging with the side edge of the solar cell;
a third horizontal board, wherein a second gap is formed between the second and third horizontal boards;
a second vertical board connected to the second and third horizontal boards, wherein at least a portion of the second horizontal board and at least a portion of the third horizontal board protrude from the second vertical board, such that an open accommodating space is defined between the second horizontal board, the second vertical board, and the third horizontal board; and
at least a support element detachably positioned in the accommodating space, wherein a top surface of the support element is abutted against the second horizontal board, and a bottom surface of the support element is abutted against the third horizontal board.
